(19) United States
(12) Patent Application Publication
(10) Pub. No.: US 2007/0228497 A1
(43) Pub. Date: Oct. 4, 2007

(54) Semiconductor device and method for fabricating the same

(75) Inventor: Satoshi Shimizu, Yamanashi (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: EUDYNA DEVICES INC., Yamanashi (JP)

(21) Appl. No.: 11/727,677

(22) Filed: Mar. 28, 2007

(30) Foreign Application Priority Data
Mar. 31, 2006 (JP) 2006-101188

(51) Int. Cl. H01L 29/76; H01L 29/94; H01L 31/00

(52) U.S. Cl. 257/409

(57) ABSTRACT

A semiconductor device includes: a gate electrode formed on a semiconductor layer; a source electrode and a drain electrode respectively provided at sides of the gate electrode; and a first field plate provided in a region between the drain electrode and an element isolation region located in an extension of a finger direction that is a longitudinal direction of the drain electrode.

### BACKGROUND OF THE INVENTION

1. Field of the Invention

The present invention generally relates to a semiconductor device and a method for fabricating the same, and more particularly, to a semiconductor device having a field plate located in a region between a drain electrode and an element isolation region in the longitudinal direction of the drain electrode and a method for fabricating such a semiconductor device.

2. Description of the Related Art

A field effect transistor (FET) is used as a semiconductor device that amplifies high frequency signals such as microwaves. The following are known as FETs: an LD-MOS (Laterally Diffused MOS) FET, an N-channel MOS FET, a P-channel MOS FET, a HEMT (High Electron Mobility Transistor) using a GaAs-base semiconductor or a GaN-base semiconductor, and a MESFET (Metal Semiconductor Transistor FET).

An electrode called field plate may be provided on a semiconductor layer between the gate and drain electrodes of an FET directed to amplifying large powers. Japanese Patent Application Publication No. 2005-294584 discloses a device with a field plate provided between the gate and drain electrodes of an LD-MOS FET (specifically, FIG. 9). The field plate is set at a given potential (which may be the ground potential as described in the above document), so that the intensity of the electric field between the gate and drain electrodes can be relaxed. The field plate provided in a region having a large strength of electric field equalizes the electric field intensity between the gate and drain electrodes, so that the source-drain breakdown voltage or gate-drain breakdown voltage can be improved. This structure enables high-power amplification.

Even when the field plate is provided between the gate and drain electrodes, however, there is a case that satisfactory source-drain breakdown voltage or gate-drain breakdown voltage may not be available.

### SUMMARY OF THE INVENTION

The present invention has been made taking into consideration the above and aims at improving the source-drain or gate-drain breakdown voltage. According to an aspect of the present invention, there is provided a semiconductor device including: a gate electrode formed on a semiconductor layer; a source electrode and a drain electrode respectively provided at sides of the gate electrode; and a first field plate provided in a region between the drain electrode and an element isolation region located in an extension of a finger direction that is a longitudinal direction of the drain electrode. It is thus possible to relax the electric field intensity in the semiconductor layer between the drain electrode and the element isolation region and to improve the source-drain breakdown voltage or the gate-drain breakdown voltage.

The semiconductor device may be configured so as to further include a second field plate provided in a region between the gate electrode and the drain electrode. The second filed plate further improves the source-drain breakdown voltage or the gate-drain breakdown voltage.

The semiconductor device may be configured so that the first field plate and the second field plate are connected. It is thus possible to easily set the first and second field plates at an identical potential.

The semiconductor device may be configured so as to further include an insulation layer provided on the semiconductor layer, wherein the first field plate is provided on the insulation layer. A given voltage may be applied to the first field plate.

The semiconductor device may be configured so that the first field plate is connected to the source electrode. With this structure, the first field plate may be set at the ground potential, so that the source-drain breakdown voltage or the gate-drain breakdown voltage can further be improved.

According to another aspect of the present invention, there is provided a method for fabricating a semiconductor device including: forming a gate electrode on a semiconductor layer; forming a source electrode and a drain electrode respectively provided at sides of the gate electrode; and forming a first field plate provided in a region between the drain electrode and an element isolation region located in an extension of a finger direction that is a longitudinal direction of the drain electrode. It is thus possible to relax the electric field intensity in the semiconductor layer between the drain electrode and the element isolation region and to improve the source-drain breakdown voltage or the gate-drain breakdown voltage.

The method may be configured so as to further include forming a second field plate provided in a region between the gate electrode and the drain electrode. The second filed plate further improves the source-drain breakdown voltage or the gate-drain breakdown voltage.

The method may be configured so that the first and second field plates are simultaneously formed. The method may further include forming an insulation layer on the semiconductor layer, wherein the second field plate is formed on the insulation layer.

The method may be configured so that the first field plate is formed so as to be connected to the source electrode. It is thus possible to easily set the first and second field plates at an identical potential.

### BRIEF DESCRIPTION OF THE DRAWINGS

Other objects, features and advantages of the present invention will become more apparent from the following detailed description when read in conjunction with the accompanying drawings, in which:

FIG. 1 is a plan view of an LD-MOS FET in accordance with a first embodiment of the present invention;

FIG. 2A is a cross-sectional view taken along a line A-A shown in FIG. 1;

FIG. 2B is a cross-sectional view taken along a line B-B shown in FIG. 1; and

FIGS. 3A and 3B are cross-sectional views taken along the line A-A observed during a process for fabricating the LD-MOS FET in accordance with the first embodiment.

### DESCRIPTION OF THE PREFERRED EMBODIMENTS

A description will now be given of embodiments of the present invention with reference to the accompanying drawings.

### First Embodiment

The inventors found out that the drain-source breakdown voltage can be improved by lengthening the distance between the drain electrode and an element isolation region in the directions in which fingers of the drain electrodes run. Further, the inventors investigated luminescence emission when breakdown takes place and found out that breakdown occurs in the direction of fingers that coincides with the longitudinal direction of the drain electrode. This shows that a strong electrical field intensity exists in the direction in which the fingers of the drain electrodes run and causes breakdown. Taking the above into consideration, a field plate is provided in the direction in which the fingers of the drain electrode run.

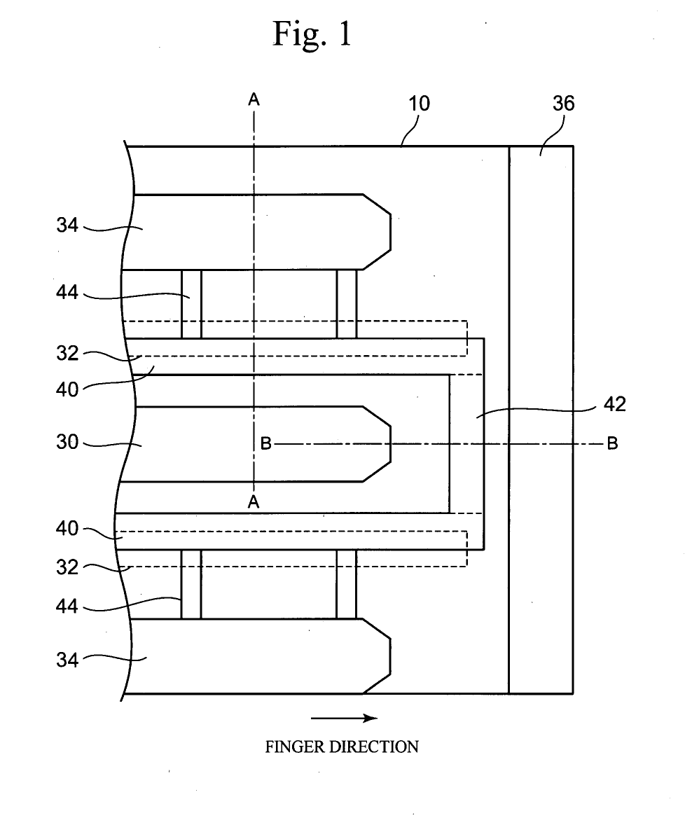

FIG. 1 is a plan view of an LD-MOS FET in accordance with a first embodiment. A gate insulation film 31 is provided on a silicon semiconductor layer 12. Fingers of a gate electrode 32 are provided on the gate insulation film 31. On the silicon semiconductor layer 12, there are provided fingers of a source electrode 34 and a drain electrode 30 between which the finger of the gate electrode 32 is interposed. Actually, the fingers may be a few μm to hundreds of μm long, and FIG. 1 shows only end portions of the whole fingers. The fingers are arranged side by side in width directions thereof perpendicular in the finger directions in which the fingers run. An element isolation region 36 is provided in extensions of the finger directions. Second field plates 40 are provided so as to run over the gate electrodes 32 and extend towards the drain electrode 30. That is, the second field plates 40 are provided in regions between the drain electrode 30 and the gate electrodes 32. The second field plates 40 are electrically connected to the associated source electrodes 34 by connecting portions 44. A first field plate 42 is provided in a region between the drain electrode 30 and the element isolation region 36 located in the extension of the finger direction of the drain electrode 30. The first field plate 42 may partially or totally extend over the element isolation region 36.

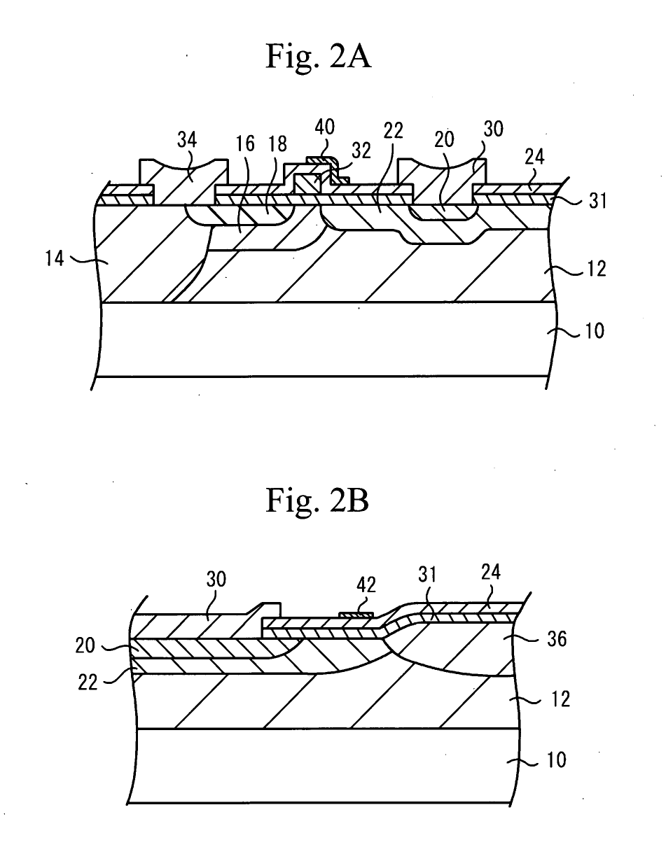

FIGS. 2A and 2B are respectively cross-sectional views taken along lines A-A and B-B shown in FIG. 1, respectively. Referring to FIG. 2A, the semiconductor layer 12 is provided on a semiconductor substrate 10. A P-type sinker region 14 penetrated through the semiconductor layer 12 from the surface to the substrate 10 is provided. The gate electrode 32 is provided on the semiconductor layer 12. A source region 18 and an offset region 22 are located at both sides of the gate electrode 32 and are formed in the semiconductor layer 12. A channel region 16 is provided so as to cover the source region 18 from the semiconductor layer 12 below the gate electrode 32 to the P-type sinker region 14. The source electrode 34 is provided on the semiconductor layer 12 so as to contact the sinker region 14 and the source region 18. The drain electrode 30 is provided on the semiconductor layer 12 so as to contact a drain region 20. An insulation layer 24 is provided so as to cover the semiconductor layer 12 and the gate electrode 32. The second field plate 40 is provided on the insulation layer 24 from the gate electrode 32 towards the drain electrode 30. That is, the second field plate 40 is provided between the gate electrode 32 and the drain electrode 30.

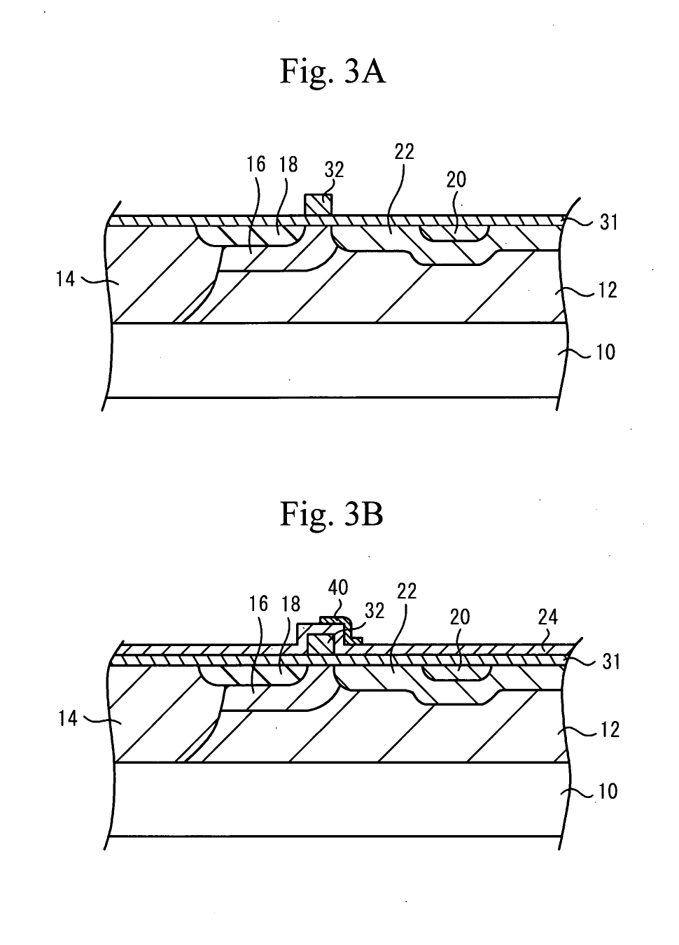

A description will now be given, with reference to FIGS. 3A and 3B, of a method of fabricating the semiconductor device in accordance with the first embodiment. Referring to FIG. 3A, the P-type silicon semiconductor layer 12 having a high resistance is epitaxially grown. The semiconductor layer 12 is selectively oxidized to thus form the element isolation region 36 by a field oxide (this is not shown in FIG. 3A; see FIG. 2B). Then, boron (B), for example, is ion-implanted in the semiconductor layer 12 to thus from the P-type sinker region 14. Thereafter, the gate insulation film 31 is provided on the entire surface of the wafer. Then, the gate electrode 32 composed of a polysilicon layer and a tungsten layer is formed on the gate insulation film 31. Then, boron, for example, is ion-implanted through the gate insulation film 31 to thus form the channel region 16. After that, phosphorus (P) is ion-implanted to thus form the source region 18, the drain region 20 and the offset region 22.

Referring to FIG. 3B, the insulation layer 24, which may, for example, be a silicon oxide layer, is formed on the semiconductor layer 12. Then, a tungsten silicide (WSi) layer is formed by sputtering or the like. Then, the WSi layer is etched in given regions, so that the first field plate 42, the second field plate 40 and the connecting portions 44 can be formed simultaneously (the second field plate 40 and the connecting portions 44 are not illustrated in FIG. 3B).

At that time, the first field plate 42 is provided between the drain electrode 30 and the element isolation region 36 in the finger direction of the drain electrode 30. For example, the first field plate 42 may be formed so as to contact the second field plate 40 and extends towards the finger direction of the drain electrode 30. The first field plate 42 is formed so as to be electrically connected, via the second field plate 40 and the connecting portions 44, to the source-electrode 34.

As shown in FIG. 2A, openings are formed in the insulation film 24. Then, the source electrode 34 and the drain electrode 30 made of, for example, aluminum (Al) is formed on the semiconductor layer 12. Thereafter, a dielectric film and an interconnect metal are formed so that the LD-MOS FET of the first embodiment can be completed.

Table 1 shows the characteristics of the LD-MOS FET configured in accordance with the first embodiment and a comparative LD-MOS FET without the first field plate 42 (comparative example). The embodiment LD-MOS FET and the comparative LD-MOS FET had a specification such that the gate length is 0.6 μm, the widths of the first field plate 42 and the second field plate 40 are 1 μm, and the distance between the first field plate 42 and the drain region 20 is 8 μm. Symbols Vth and BVdss in Table 1 are respectively the threshold voltage and the source-drain voltage at a drain-source voltage Vds of 28 V. The values of parameters gm, Cgs, Cds, Ri, Rds and MSG are those per a gate width of 1 mm computed from small-signal characteristics of high-frequency waves at a Vds of 28 V and Ids of 5.0 mA/mm. The symbols gm, Cgs, Cds, Ri, Rds and MSG are defined as follows:

gm: mutual conductance;

Cgs: gate-source capacitance;

Cds: drain-source capacitance;

Ri: input resistance;

Rds: drain-source resistance; and

MSG: maximum stable power gain.

TABLE 1

| | | | gm | Cgs | Cgd | Cds | Ri | Rds | MSG |
|---|---|---|---|---|---|---|---|---|---|
| | Vth V | BVdss V | mS/mm | pF/mm | fF/mm | pF/mm | Ωmm | Ωmm | dB |
| COMPARATIVE | 2.60 | 60 | 15 | 0.90 | 13 | 0.3 | 21 | 7000 | 20 |
| EMBODIMENT | 2.58 | 64 | 17 | 0.91 | 11 | 0.3 | 22 | 9200 | 21 |

Referring to Table 1, the parameters VBdss, Cgd, Rds and MSG are improved by providing the first field plate 42. As has been described, there is a position between the drain electrode 30 and the element isolation region 36 at which a strong field effect intensity is observed. With the above in mind, the first field plate 42 is located between the drain electrode and the element isolation region 36 located in the extension of the finger direction of the drain electrode 30. The first field plate 42 weakens the strong electric field intensity and equalizes the electric field intensity.

In the above-mentioned first embodiment, the first field plates 42 are provided at both sides of the drain electrode 30 in the finger direction (only one first field plate 42 is illustrated in FIG. 1). The first field plate 42 may be provided at only one of the sides of the drain electrode 30. In the above-mentioned first embodiment, the first field plate 42 is electrically connected to the second field plate 40. Alternatively, the first field plate 42 may be separate from the second field plate 40. The second field plate 40 can further improve the source-drain breakdown voltage or the gate-drain breakdown voltage. However, it is to be noted that degradation of the breakdown voltage that occurs in the finger direction of the drain electrode 30 can be improved even in the absence of the second field plate 40. The first field plate 42 may be partially formed in the region between the drain electrode 30 and the element isolation region 36 located in the longitudinal direction of the drain electrode 30. Preferably, the first field plate 42 and the second field plate 40 are formed in regions in which a large electric field intensity is observed. These regions may be arbitrarily changed by changing the composition of the semiconductor layer 12 and the dose of doped ion.

The given voltage is applied to the first field plate 42 in operation, so that the electric field intensity in the semiconductor layer can be relaxed. Preferably, the first field plate 42 may be set at the ground potential in order to relax the electric field intensity in the semiconductor layer 12. For example, as in the case of the first embodiment, the first field plate 42 is electrically coupled to the source electrode 34 via the second field plate 40. With this arrangement, the firs field plate 42 can be set at the ground potential without a new wiring line. Another method may be applied to set the first field plate 42 at the ground potential. The first field plate 42, the second field plate 40 and the connecting portions 44 may be formed simultaneously, so that the fabrication process can be simplified.

The present invention is not limited to the exemplary LD-MOD FET of the first embodiment, but may include FETs using a Si-base, GaAs-base, or GaN-base material.

Further, the present invention is not limited to the specifically described embodiments and variations, but includes other embodiments and variations without departing from the scope of the present invention.

The present application is based on Japanese Patent Application No. 2006-101188 filed Mar. 31, 2006, the entire disclosure of which is hereby incorporated by reference.

What is claimed is:

1. A semiconductor device comprising:
a gate electrode formed on a semiconductor layer;
a source electrode and a drain electrode respectively provided at sides of the gate electrode; and
a first field plate provided in a region between the drain electrode and an element isolation region located in an extension of a finger direction that is a longitudinal direction of the drain electrode.

2. The semiconductor device as claimed in claim 1, further comprising a second field plate provided in a region between the gate electrode and the drain electrode.

3. The semiconductor device as claimed in claim 2, wherein the first field plate and the second field plate are connected.

4. The semiconductor device as claimed in claim 1, further comprising an insulation layer provided on the semiconductor layer, wherein the first field plate is provided on the insulation layer.

5. The semiconductor device as claimed in claim 1, wherein a given voltage is applied to the first field plate.

6. The semiconductor device as claimed in claim 1, wherein the first field plate is connected to the source electrode.

7. A method for fabricating a semiconductor device comprising:
forming a gate electrode on a semiconductor layer;
forming a source electrode and a drain electrode respectively provided at sides of the gate electrode; and
forming a first field plate provided in a region between the drain electrode and an element isolation region located in an extension of a finger direction that is a longitudinal direction of the drain electrode.

8. The method as claimed in claim 7, further comprising forming a second field plate provided in a region between the gate electrode and the drain electrode.

9. The method as claimed in claim 7, wherein the first and second field plates are simultaneously formed.

10. The method as claimed in claim 7, further comprising forming an insulation layer on the semiconductor layer, wherein the second field plate is formed on the insulation layer.

11. The method as claimed in claim 7, wherein the first field plate is formed so as to be connected to the source electrode.
